(19) United States
(12) Patent Application Publication
(10) Pub. No.: US 2010/0052160 A1
(43) Pub. Date: Mar. 4, 2010

(54) BUMP STRUCTURE AND METHOD FOR FABRICATING THE SAME

(76) Inventors: Wei-Hao SUN, Taipei City (TW); Pao-Yun Tang, Taipei City (TW)

Correspondence Address: SINORICA, LLC, 2275 Research Blvd., Suite 500, ROCKVILLE, MD, 20850, US

(21) Appl. No.: 12/255,416

(22) Filed: Oct. 21, 2008

(30) Foreign Application Priority Data
Aug. 29, 2008 (TW) 97133263

(51) Int. Cl. H01L 23/52; H01L 21/44

(52) U.S. Cl. 257/737; 438/613; 257/E23.141; 257/E21.476

(57) ABSTRACT

The present invention discloses a bump structure and a method for fabricating the same. The bump structure of the present invention comprises a semiconductor substrate having a plurality of connection pads; a passivation layer covering the substrate and having openings each corresponding to one connection pad, wherein the openings reveal a portion of each connection pad to form a plurality of electrical-connection areas; an elastic layer formed on the passivation layer; and a plurality of bumps each formed corresponding to one electric-connection area and extending to the elastic layer, whereby the elasticity and deformability of the bumps is enhanced. The present invention uses a larger-texture (≧20 μm) patterning process to fabricate an appropriate patterned elastic layer (having parallel lines, strips, or saw teeth) to enhance the elasticity and deformability of the bumps, whereby the bump structure of the present invention can apply to a fine-pitch IC.

### BACKGROUND OF THE INVENTION

1. Field of the Invention

The present invention relates to a bump structure and a method for fabricating the same, particularly to a novel smart bump structure and a method for fabricating the same.

2. Description of the Related Art

LCD fabrication includes an array process, a cell process and a module process. The primary objective of the module process is to package the driver IC. The module process further includes a COG (Chip on Glass) process, an FOG (Film on Glass) process, and an FOB (Film on Board) process.

Among the three main processes of LCM (LCD module), COG technology is the key design to reduce the cost for its high bonding density and low cost. COG is a module-packaging technology for a high-pin-count and fine-pitch FPD (Flat Panel Display). The COG module-packaging technology is characterized in having the least joints between the IC signal source and the glass substrate and having no need of using a flexible substrate. COG can prevent leads from the bending-induced breakage, which is likely to occur in a TCP (Tape Carrier Package) process; therefore, it can promote the reliability of products.

The conventional COG driver IC contains bumps to implement conducting the signals of a driver IC to LCD and facilitate switching the pixel signals and the frames. Refer to FIG. 1 a diagram schematically showing a conventional bump structure. The conventional bump structure comprises a semiconductor substrate 12 having a connection pad 10, wherein the connection pad 10 is made of a metallic material, such as aluminum, copper or an alloy; a passivation layer 14 covering the substrate 12 and a portion of the connection pad 10 and defining the region where the connection pad 10 is electrically coupled to an external circuit; an under-bump metal layer 16 formed on the passivation layer 14 and the connection pad 10 revealed from the passivation layer 14, wherein the under-bump metal layer 16 is made of a metallic material, such as aluminum, titanium, tungsten, gold, or an alloy; and a bump 18 formed on the under-bump metal layer 16, wherein the bump 18 is usually made of gold. As the bump 18 is entirely made of a metallic material, the elasticity and deformability thereof is insufficient for the NFC (Non-Conductive Film) process of the COG technology.

Thus, a smart bump structure was developed to solve the abovementioned problem. Refer to FIG. 2(a) and FIG. 2(b). The smart bump structure 20 comprises a semiconductor substrate 22 having a connection pad 21; a passivation layer 23 covering the substrate 22 and a portion of the connection pad 21; a PI layer (elastic layer) 24 covering the passivation layer 23 and a portion of the connection pad 21 revealed from the passivation layer 23 and defining the region where the connection pad 21 is electrically coupled to an external circuit; a under-bump metal layer 25 formed on the PI layer 24 and the connection pad 21 revealed from the PI layer 24; and a bump 26 formed on the under-bump metal layer 25. In the smart bump structure 20, each bump 26 has a patterned island-like PI layer 24 therebelow, which can enhance the elasticity of the entire bump structure and improve the reliability of the COG NCF process. Thus, in the fabrication of the smart bump structure 20, the island-like PI layers 24 have to be fabricated beforehand on the positions where the bumps 26 are to be formed.

With the increasing number of pixels and the advance of IC design and IC fabrication, the pins that an IC contains increases greatly, and the pitch of pins also becomes finer. Correspondingly, the width of the bump has to be reduced to enable IC to accommodate more of fine pitches. In general, the spacing of the bumps of a fine-pitch IC is less than 20 μm. In the photolithography of the material of the PI layer, the spacing has a lower limit of 20 μm, which is a bottleneck in fabricating the island-like elastic layers having a spacing of a (a<20 μm).

Accordingly, the present invention proposes a novel bump structure and a method for fabricating the same to overcome the conventional problems.

### SUMMARY OF THE INVENTION

The primary objective of the present invention is to provide a bump structure and a method for fabricating the same, which uses a larger-texture (≧20 μm) patterning process to fabricate an elastic layer enhancing the elasticity and deformability of bumps, whereby the bump structure of the present invention can apply to a fine-pitch IC.

Another objective of the present invention is to provide a bump structure and a method for fabricating the same, wherein the sawtooth-shape elastic layer favors draining the residual conductive glue of the ACF (Anisotropic Conductive Film) electric connection process.

To achieve the abovementioned objectives, the present invention proposes a bump structure, which comprises a semiconductor substrate having a plurality of connection pads thereof; a passivation layer covering the substrate and having openings each formed corresponding to one of the connection pads, wherein the openings reveal a portion of each of the connection pads to form a plurality of electric-connection areas; an elastic layer covering the passivation layer; and a plurality of bumps each formed corresponding to one of the electric-connection areas and extending to the elastic layer.

The present invention also proposes a method for fabricating a bump structure, which comprises steps: forming a plurality of connection pads on a semiconductor substrate; forming an elastic layer on the semiconductor substrate; and forming a plurality of bumps each corresponding to one of the connection pads and extending to the elastic layer.

Below, the embodiments are described in detail to make easily understood the objectives, technical contents, characteristics and accomplishments of the present invention.

### BRIEF DESCRIPTION OF THE DRAWINGS

FIG. 1 is a sectional view schematically showing a conventional bump structure;

FIG. 2(a) is a sectional view schematically showing a conventional smart bump structure;

FIG. 2(b) is a top view schematically showing a conventional smart bump structure;

FIGS. 3(a)-3(c) are respectively a perspective view, a sectional view along Line bb′ and a layout diagram schematically showing a smart bump structure according to a first embodiment of the present invention;

FIG. 4 is a flowchart of a method for fabricating the bump structure according to the first embodiment of the present invention;

FIGS. 5(a)-5(c) are respectively a perspective view, a sectional view along Line cc′ and a layout diagram schematically showing a smart bump structure according to a second embodiment of the present invention;

FIG. 6 is a diagram schematically showing another patterned elastic layer having a sawtooth pattern according to a third embodiment of the present invention;

FIG. 7(a) is a sectional view schematically showing a smart bump structure according to a fourth embodiment of the present invention; and

FIG. 7(b) is a top view schematically showing the smart bump structure according to the fourth embodiment of the present invention.

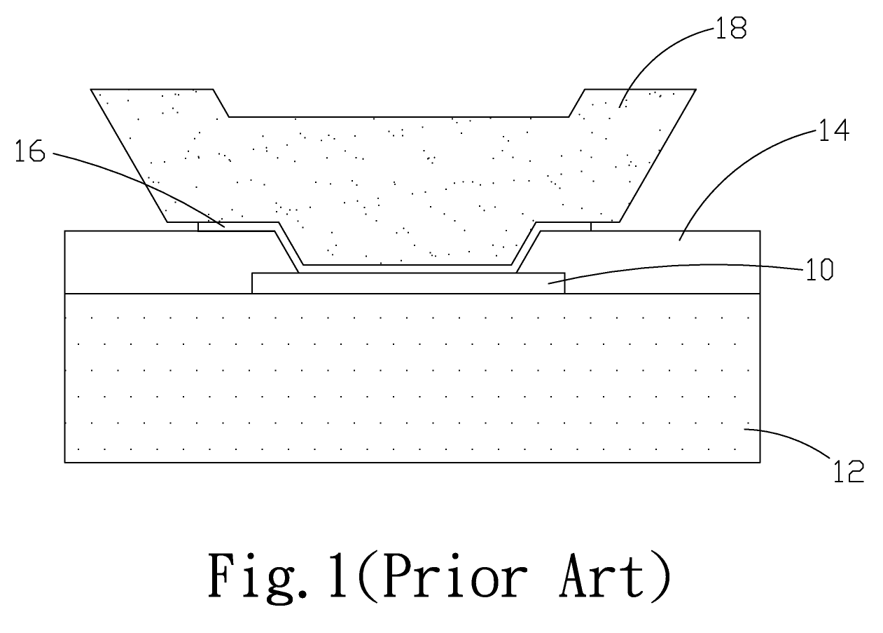

### DETAILED DESCRIPTION OF THE INVENTION

As the pitch of IC pins is growing finer and finer, the spacing of the bumps of a fine-pitch IC is required to be less than 20 μm. However, the spacing of the elastic layers of a bump structure has a photolithographic limit of 20 μm. Based on the conventional technology of the smart bump structure, the present invention proposes a novel smart bump structure to overcome such a situation and provide a greater allowance for the bumping houses to easily fabricate smart bump structures.

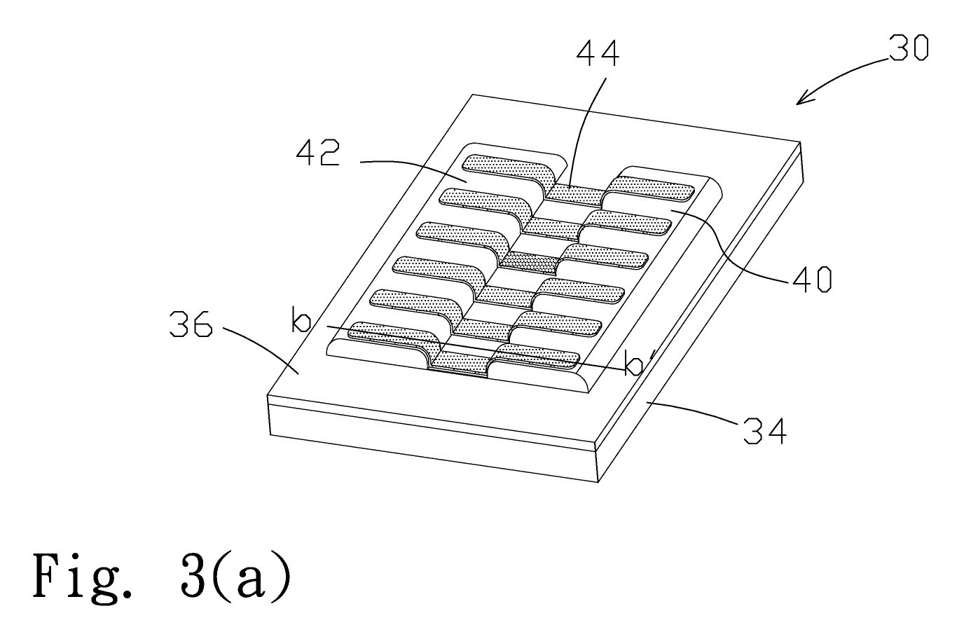

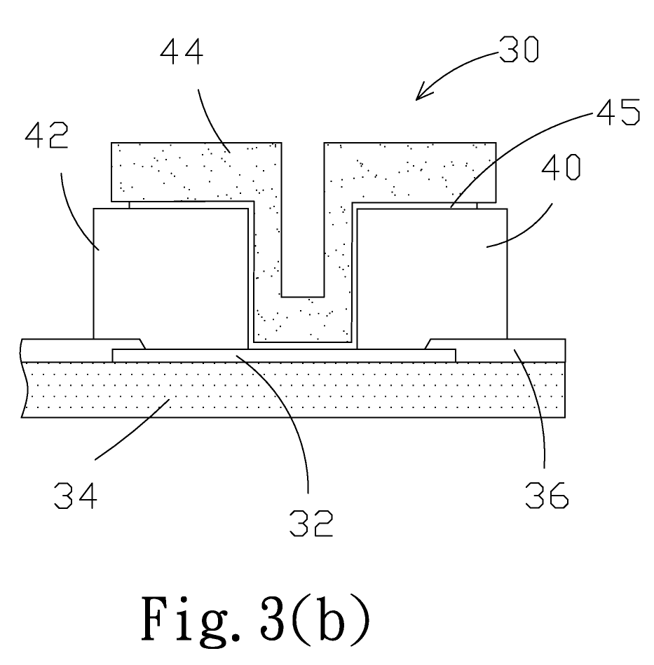

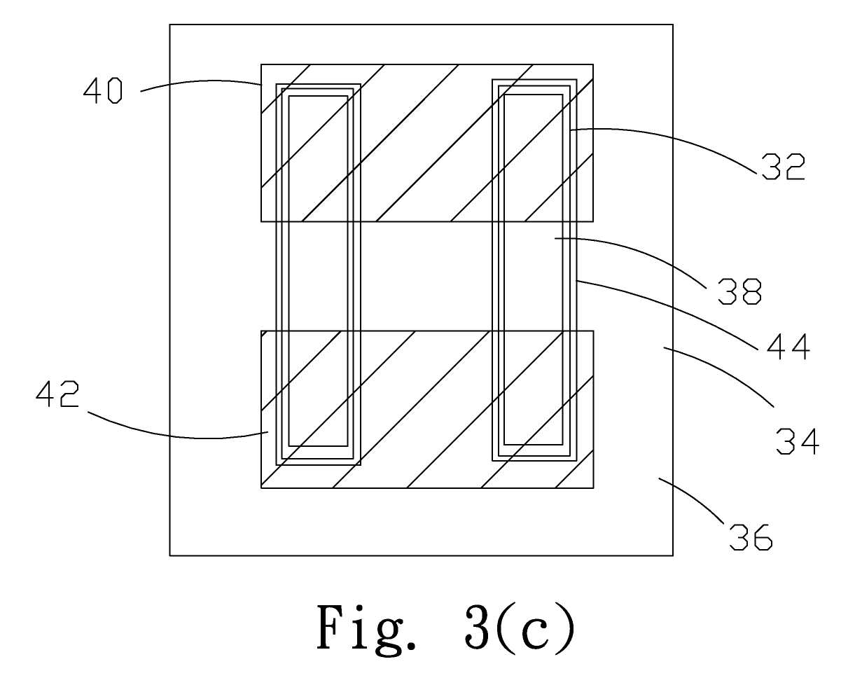

Refer to from FIG. 3(a) to FIG. 3(c) respectively a perspective view, a sectional view along Line bb′ and a layout diagram of a smart bump structure according to a first embodiment of the present invention. The smart bump structure of the first embodiment is different from the conventional smart bump structure in that the patterned elastic layer carries at least two bump structures in the first embodiment.

In the first embodiment of the present invention, the smart bump structure 30 comprises a semiconductor substrate 34 having a plurality of connection pads 32; a passivation layer 36 covering the substrate 34 and having openings each corresponding to one connection pad 32, wherein the openings reveal a portion of each connection pad 32 to form electrical-connection areas 38; a first elastic layer 40 covering the passivation layer 36 and extending to first sides of the electric-connection areas 38; a second elastic layer 42 covering the passivation layer 36 and extending to second sides of the electric-connection areas 38, wherein the first and second elastic layers 40 and 42 are made of a non-conductive material having an elasticity better than that of a metallic material, such as polyimide; and a plurality of bumps 44 each formed corresponding to one electric-connection area 38, wherein two ends of each bump 44 respectively extend to the first and second elastic layers 40 and 42. In the first embodiment, the bump 44 may further have an under-bump metal layer 45.

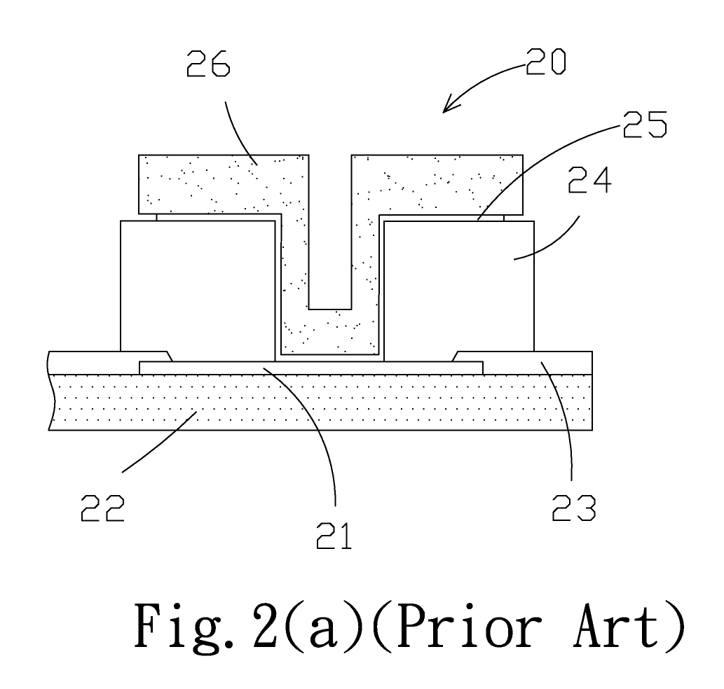

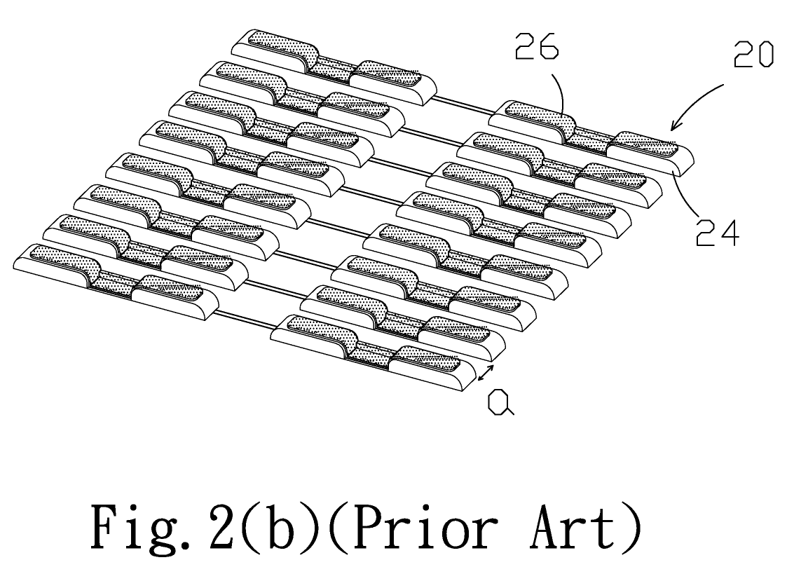

In the abovementioned structure, first ends of the bumps 44 are all positioned on the first elastic layer 40, and second ends of the bumps 44 are all positioned on the second elastic layer 42. In other words, the first elastic layer 40 supports all the forces applied onto the first ends of the bumps 44, and the second elastic layer 42 supports all the forces applied onto the second ends of the bumps 44. As the first and second elastic layers 40 and 42 are made of a material having an elasticity better than that of a metallic material, the first and second elastic layers 40 and 42 can increase the elasticity and deformability of the metallic bumps 44 in the succeeding electric-connection process. In the first embodiment, the first and second elastic layers 40 and 42 only need pattering into long-strip structures. In the present invention, it is unnecessary to photolithographically fabricate the first and second elastic layers 40 and 42 into discrete island-like structures shown in FIG. 2(b). Therefore, the present invention is completely free from the photolithographic limit of 20 μm spacing of elastic layers.

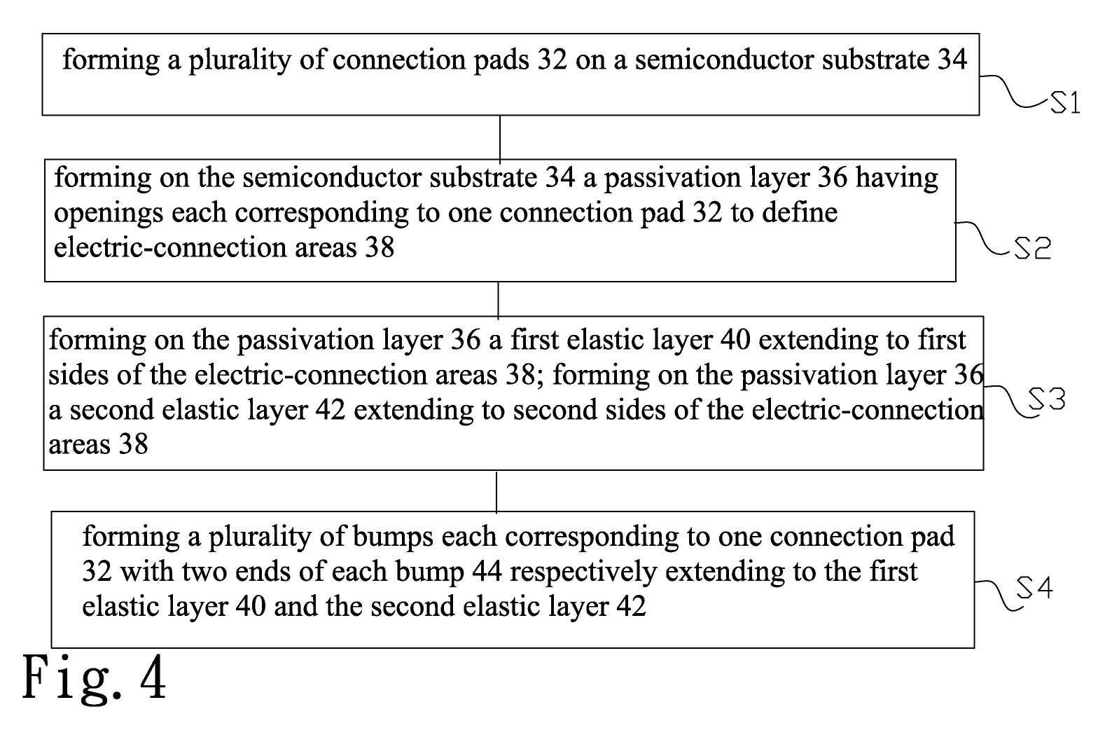

Refer to FIG. 4 a flowchart of a method for fabricating a bump structure according to the first embodiment of the present invention. In Step S1, a plurality of connection pads 32 is formed on a semiconductor substrate 34. In Step S2, a passivation layer 36 is formed on the substrate 34; the passivation layer 36 has openings each corresponding to one connection pad 32, and the openings reveal a portion of each connection pad 32 to form electric-connection areas 38. In Step S3, a first elastic layer 40 is formed on the passivation layer 36 and extends to first sides of the electric-connection areas 38; a second elastic layer 42 is formed on the passivation layer 36 and extends to second sides of the electric-connection areas 38. In Step S4, a plurality of bumps 44 is formed over the connection pads 32, and two ends of each bump 44 respectively extend to the first elastic layer 40 and the second elastic layer 42.

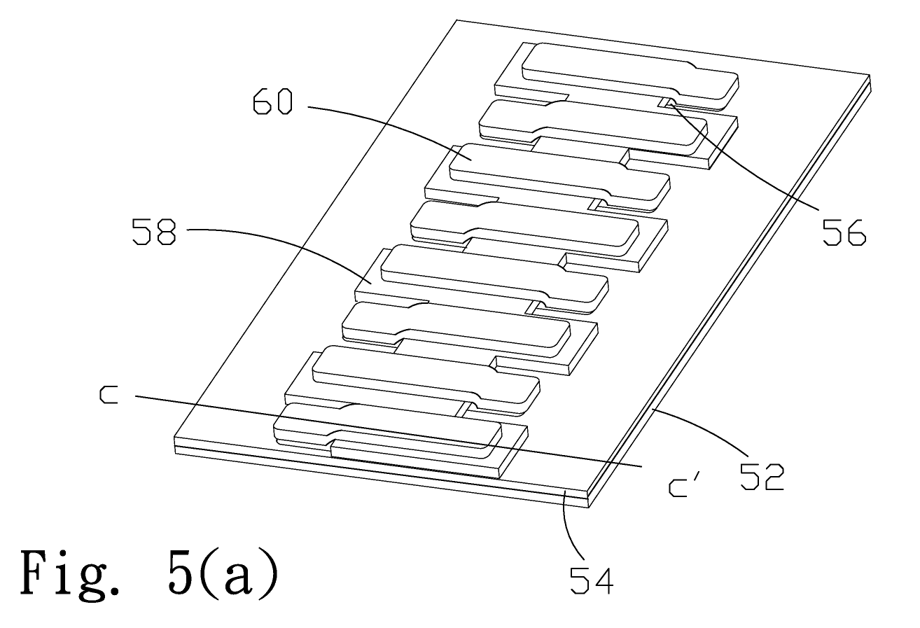

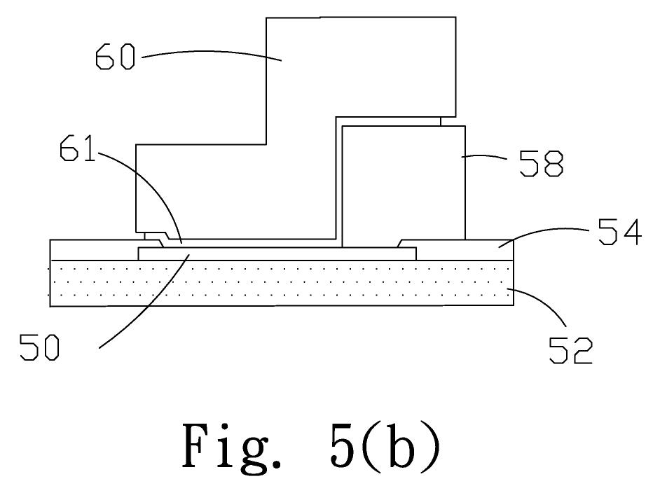

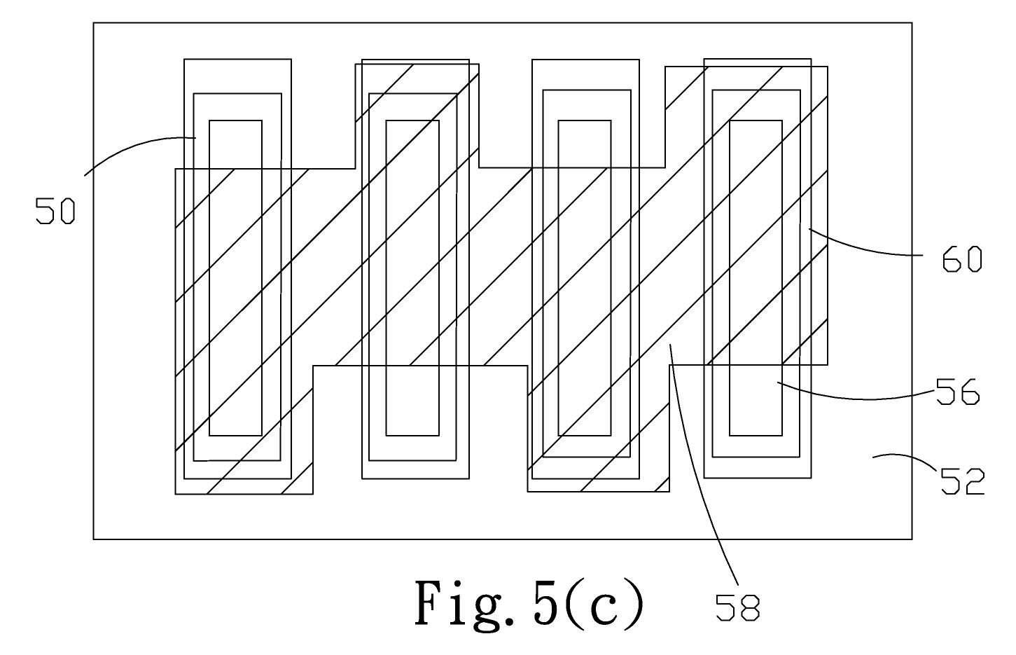

Refer to from FIG. 5(a) to FIG. 5(c) respectively a perspective view, a sectional view along Line cc′ and a layout diagram of a smart bump structure according to a second embodiment of the present invention. In the second embodiment, the elastic layer of the smart bump structure is appropriately modified to meet the pressure and deformation of the bumps in the succeeding electric-connection process. In the second embodiment, the bump structure comprises a semiconductor substrate 52 having a plurality of connection pads 50; a passivation layer 54 covering the substrate 52 and having openings each corresponding to one connection pad 50, wherein the openings reveal a portion of each connection pad 50 to form electrical-connection areas 56; a patterned elastic layer 58 covering the passivation layer 54 and extending to a portion of each electric-connection area 56, wherein the patterned elastic layer 58 may be made of polyimide and may have a sawtooth pattern; and a plurality of bumps 60 each formed corresponding to one electric-connection area 56, extending to the patterned elastic layer 58 and electrically coupled to the electric-connection area 56 revealed by the patterned elastic layer 58, wherein the elastic layer 58 covered by the bumps 60 increases the elasticity and deformability of the bumps 60. In the second embodiment, the bump 60 may further have an under-bump metal layer 61.

In the abovementioned structure, the elastic layer is fabricated with a larger-texture patterning process, which produces structures greater than the discrete island-like structures shown in FIG. 2. Therefore, it is unnecessary to fabricate spacings smaller than the photolithographic limit 20 μm in the second embodiment of the present invention.

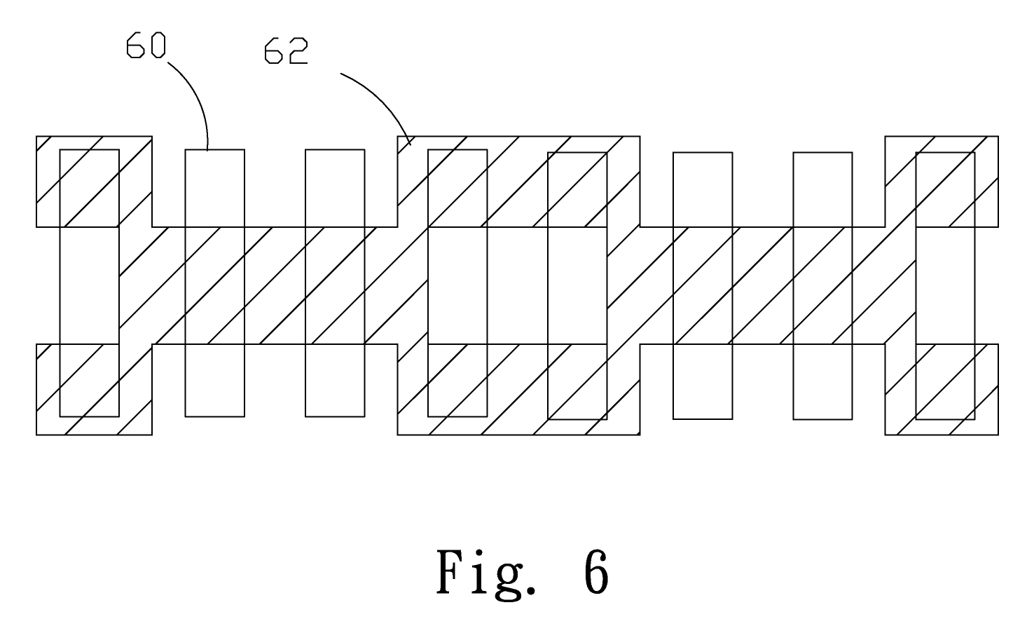

Refer to FIG. 6 a diagram schematically showing another patterned elastic layer having a sawtooth pattern according to a third embodiment of the present invention. The elastic layer 62 in FIG. 6 is different from the elastic layer 58 in FIG. 5 in that the elastic layer 62 is modified to increase the total elasticity of the bumps and meet the pressure applied to the bumps in the succeeding process. The sawtooth pattern of the elastic layer favors draining the residual conductive glue of ACF (Anisotropic Conductive Film).

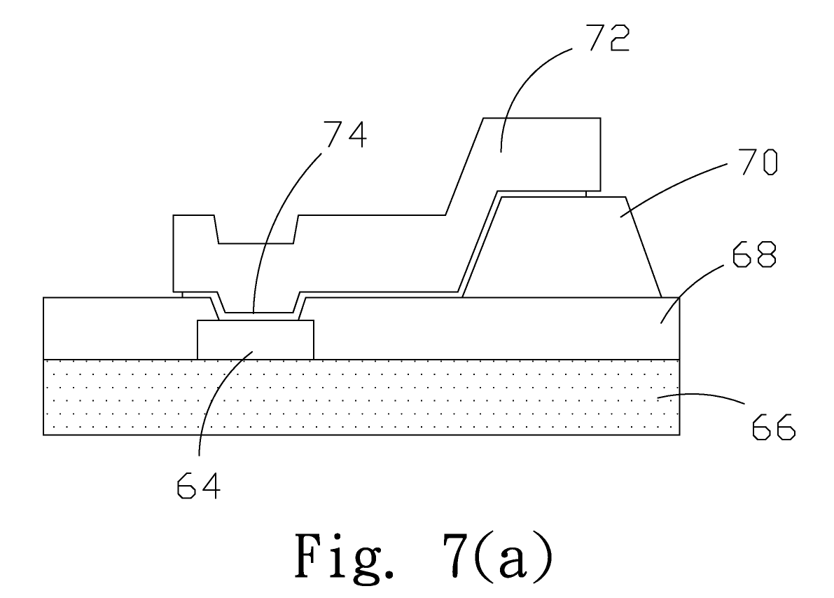

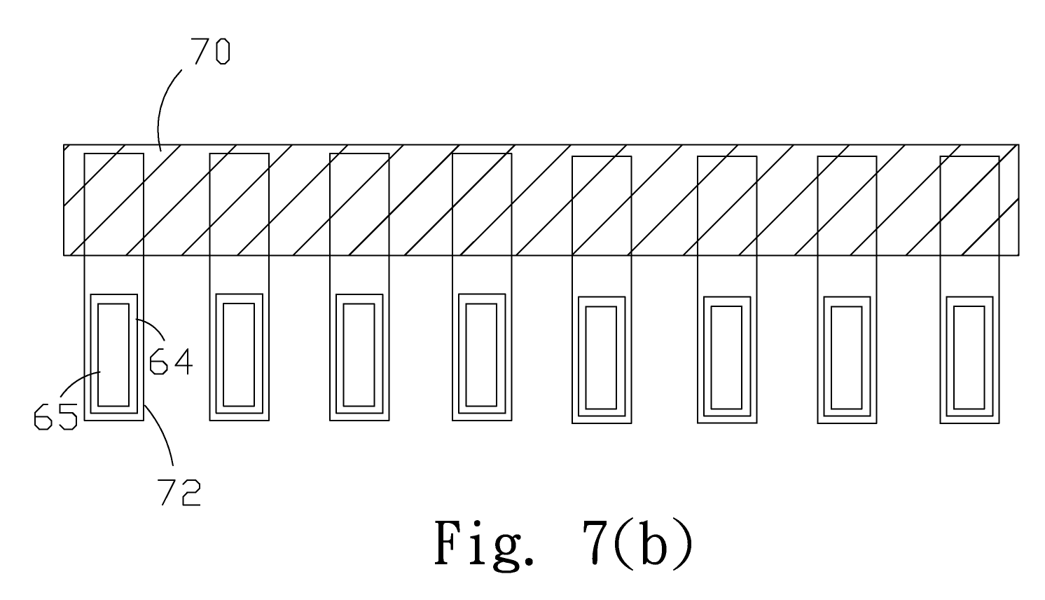

Refer to FIG. 7(a) and FIG. 7(b) respectively a sectional view and a top view of a smart bump structure according to a fourth embodiment of the present invention. In the fourth embodiment of the present invention, the smart bump structure comprises a semiconductor substrate 66 having a plurality of connection pads 64; a passivation layer 68 covering the substrate 66 and having openings each corresponding to one connection pad 64, wherein the openings reveal a portion of each connection pad 64 to form electrical-connection areas 65; an elastic layer 70 formed on the passivation layer 68; and a plurality of bumps 72 each formed corresponding to one electrical-connection area 65 and extending to over the elastic layer 70. In the fourth embodiment, the bump 72 may further have an under-bump metal layer 74. The fourth embodiment is different from the abovementioned embodiments in that the elastic layer of the fourth embodiment does not extends to the electrical-connection areas but only covers the passivation layer.

In conclusion, the present invention proposes a novel bump structure and a method for fabricating the same. The bump structure of the present invention comprises a semiconductor substrate having a plurality of connection pads; a passivation layer covering the substrate and having openings each corresponding to one connection pad, wherein the openings reveal a portion of each connection pad to form a plurality of electrical-connection areas; at least one elastic layer formed on the passivation layer; and a plurality of bumps each formed corresponding to one electric-connection area and extending to the elastic layer, whereby the elasticity and deformability of the bumps is enhanced. The present invention uses a larger-texture (≧20 μm) patterning process to fabricate a patterned elastic layer (having parallel lines, strips, or saw teeth) to enhance the elasticity and deformability of the bumps, whereby the smart bump structure of the present invention can apply to a fine-pitch IC.

The embodiments described above are only to exemplify the present invention but not to limit the scope of the present invention. Therefore, any equivalent modification or variation according to the characteristics or spirit of the present invention is to be also included within the scope of the present invention.

What is claimed is:

1. A bump structure comprising
a semiconductor substrate having a plurality of connection pads thereon;
a passivation layer covering said semiconductor substrate and having a plurality of openings each corresponding to one of said connection pads, wherein said openings reveal a portion of each of said connection pads to form a plurality of electric-connection areas;
an elastic layer formed on said passivation layer; and
a plurality of bumps each formed corresponding to one of said electric-connection areas and extending to said elastic layer.

2. The bump structure according to claim 1, wherein said elastic layer is made of photo sensitive polymer.

3. The bump structure according to claim 1, wherein each of said bumps has an under-bump metal layer.

4. The bump structure according to claim 1, wherein said bumps are made of an electrically-conductive material.

5. The bump structure according to claim 4, wherein said electrically-conductive material is copper or gold.

6. The bump structure according to claim 1, wherein said elastic layer is patterned to have a sawtooth pattern.

7. The bump structure according to claim 1, wherein said elastic layer further comprises a first elastic layer and a second elastic layer respectively formed at two sides of a bottom of said bumps.

8. The bump structure according to claim 1 is applied to a process of fabricating a liquid crystal display module.

9. The bump structure according to claim 1, wherein said bumps are made of a non-electrically-conductive material.

10. The bump structure according to claim 1, wherein said elastic layer further extends to said electric-connection areas.

11. A bump structure comprising
a semiconductor substrate having a plurality of connection pads thereon;
an elastic layer formed on said semiconductor substrate; and
a plurality of bumps each formed corresponding to one of said connection pads and extending to said elastic layer.

12. The bump structure according to claim 11, wherein said elastic layer is made of photo sensitive polymer.

13. The bump structure according to claim 11, wherein each of said bumps has an under-bump metal layer.

14. The bump structure according to claim 11, wherein said bumps are made of copper or gold.

15. The bump structure according to claim 11, wherein said elastic layer is patterned to have a sawtooth pattern.

16. The bump structure according to claim 11, wherein said bumps are made of a non-electrically-conductive material.

17. The bump structure according to claim 11, wherein said elastic layer further extends to a portion of each of said connection pads.

18. A method for fabricating a fine-pitch bump structure comprising
forming a plurality of connection pads on a semiconductor substrate;
forming an elastic layer on said semiconductor substrate; and
forming a plurality of bumps each corresponding to one of said connection pads and extending to said elastic layer.
